(19) United States
(12) Patent Application Publication
(10) Pub. No.: US 2019/0004640 A1
(43) Pub. Date: Jan. 3, 2019

(54) MANUFACTURING METHOD FOR ORGANIC LIGHT-EMITTING DISPLAY AND DISPLAY DEVICE

(71) Applicant: Wuhan China Star Optoelectronics Semiconductor Dis play Technology Co., Ltd., Wuhan, Hubei (CN)

(72) Inventor: Jian YE, Shenzhen, Guangdong (CN)

(73) Assignee: Wuhan China Star Optoelectronics Semiconductor Dis play Technology Co., Ltd., Wuhan, Hubei (CN)

(21) Appl. No.: 15/555,635

(22) PCT Filed: Jul. 21, 2017
(86) PCT No.: PCT/CN2017/093843

§ 371 Date: Sep. 5, 2017

(30) Foreign Application Priority Data
Jun. 30, 2017 (CN) 201710524284.8

(51) Int. Cl. G06F 3/041; H01L 27/32; H01L 51/52; G06F 3/044

(52) U.S. Cl. CPC G06F 3/0412; H01L 27/323; H01L 51/0097; G06F 3/044; H01L 27/3246; H01L 51/5237

(57) ABSTRACT

A manufacturing method for an organic light-emitting display is disclosed. The method comprises steps of: providing an organic light-emitting packaging component, wherein the organic light-emitting packaging component includes a packaging thin-film layer; and forming a touch electrode layer having multiple independent self-capacitive touch sensing electrode units on the packaging thin-film layer. An organic light-emitting display is also disclosed, and including an organic light-emitting packaging component, wherein, the organic light-emitting packaging component includes a packaging thin-film layer; a touch electrode layer disposed on the packaging thin-film layer, wherein the touch electrode layer has multiple independent self-capacitive touch sensing electrode units. The present invention can realize an integration of touch and display, reduce the manufacturing process, and decrease the manufacturing cost.

### BACKGROUND OF THE INVENTION

### 1. Field of the Invention

The present invention relates to a display technology, and more particularly to a manufacturing method for organic light-emitting display and display device.

### 2. Description of Related Art

In the conventional art, a touch panel which is cooperated with a flexible organic light-emitting display is required to be manufactured individually. That is, an out-cell touch display. Then, through an optical transparent glue to adhere the touch panel to an organic light-emitting module to form a complete touch display module. FIG. 1 is a schematic diagram of a conventional organic light-emitting display. In the conventional art, the organic light-emitting display includes an alignment film 100, a buffering region 101, a first gate insulation layer 102, a second gate insulation layer 103, a dielectric layer 104, a planarization layer 105, a pixel definition layer 106, a cathode layer 107, a packaging thin film 108, a polarizer 109, a touch sensor 110, an organic light-emitting display 111, a spacer 112, an electron transport layer 113, a first GE layer 114, a second GE layer 115 and an active region 116. The touch sensor 110 is formed on the polarizer 109 which is above the packaging thin film 108 of the organic light-emitting display.

The touch sensor 110 is usually manufactured individually to form two conductive layers, respectively a driving electrode layer and a sensing electrode layer. Or, the touch sensor 110 is a single bridge structure, that is, driving electrode and the sensing electrode are located at a same layer, and a conductive bridge connects sub-electrodes which are separated and located at two sides. When a finger touch the touch sensor 110, a mutual capacitance between the driving electrode and sensing electrode is changed. Through detecting variation amount of the mutual capacitance of the driving electrode and sensing electrode, a location of the finger is detected and a corresponding operation is executed. However, the above manufacturing method not only increases the thickness of the entire cell phone, but also requires an additional adhering process, which is unfavorable for light and flexible property of the touch display panel.

### SUMMARY OF THE INVENTION

The main technology problem solved by the present invention is to provide a manufacturing method for an organic light-emitting display. The method can realize an integrated touch control and display in order to decrease a thickness of the entire product, be beneficial for lightweight and be beneficial for flexibility.

In order to solve the above technology problem, a technology solution adopted by the present invention is: providing a manufacturing method for an organic light-emitting display, comprising steps of: providing an organic light-emitting packaging component, wherein the organic light-emitting packaging component includes a packaging thin-film layer; and depositing an entire surface of a metal layer on the packaging thin-film layer; patterning the metal layer through a mask having a specific pattern in order to form a touch electrode layer having multiple independent self-capacitive touch sensing electrode units on the packaging thin-film layer; wherein, the touch electrode layer includes multiple metal meshes, and between adjacent metal meshes, an electrically disconnected point is formed.

In order to solve the above technology problem, another technology solution adopted by the present invention is: providing a manufacturing method for an organic light-emitting display, comprising steps of: providing an organic light-emitting packaging component, wherein the organic light-emitting packaging component includes a packaging thin-film layer; and forming a touch electrode layer having multiple independent self-capacitive touch sensing electrode units on the packaging thin-film layer.

Wherein, the step of forming a touch electrode layer having multiple independent self-capacitive touch sensing electrode units on the packaging thin-film layer comprises: depositing an entire surface of a metal layer on the packaging thin-film layer first; then, patterning the metal layer through a mask having a specific pattern, or forming a metal mask having a specific pattern on the packaging thin-film layer through a deposition way.

Wherein, the touch electrode layer includes multiple metal meshes, and between adjacent metal meshes, an electrically disconnected point is formed.

Wherein, the organic light-emitting packaging component includes a pixel definition layer having multiple pixels, and mesh traces of each metal mesh are formed at intervals of the pixels of the pixel definition layer.

Wherein, a material of each metal mesh is any one of silver, titanium, aluminum and molybdenum.

In order to solve the above technology problem, another technology solution adopted by the present invention is: providing an organic light-emitting display, comprising: an organic light-emitting packaging component, wherein, the organic light-emitting packaging component includes a packaging thin-film layer; and a touch electrode layer disposed on the packaging thin-film layer, wherein the touch electrode layer has multiple independent self-capacitive touch sensing electrode units.

Wherein, the touch electrode layer includes multiple metal meshes, and between adjacent metal meshes, an electrically disconnected point is formed.

Wherein, the organic light-emitting packaging component includes a pixel definition layer having multiple pixels, and mesh traces of each metal mesh are formed at intervals of the pixels of the pixel definition layer.

Wherein, each independent self-capacitive touch sensing electrode unit is led out through one or more lead wires.

The beneficial effect of the present invention is: comparing to the conventional art, the organic light-emitting display integrates the touch electrode layer having independent self-capacitive touch sensing electrode units into an upper portion of the organic light-emitting display. Accordingly, the present invention can realize an integrated touch control and display in order to decrease a thickness of the entire product, be beneficial for lightweight and be beneficial for flexibility.

### BRIEF DESCRIPTION OF THE DRAWINGS

The following will combine the drawings and the embodiments for illustrating the present invention in detail, and in the figures:

FIG. 1 is a schematic diagram of a conventional organic light-emitting display;

FIG. 2 is a flow chart of a manufacturing method for an organic light-emitting display according to an embodiment of the present invention;

FIG. 3 is a schematic diagram of an organic light-emitting display according to an embodiment of the present invention;

FIG. 4 is a schematic diagram of touch sensing electrode unit of the organic light-emitting display according to an embodiment of the present invention; and

FIG. 5 is a schematic plan view of the touch electrode layer of the organic light-emitting display according to an embodiment of the present invention.

### DETAILED DESCRIPTION OF THE PREFERRED EMBODIMENT

For better understanding of the technology solution of the present invention for the person skilled in the art, the following will combine the figures and specific embodiments for illustrating the manufacturing method for an organic light-emitting display and the display device in detail.

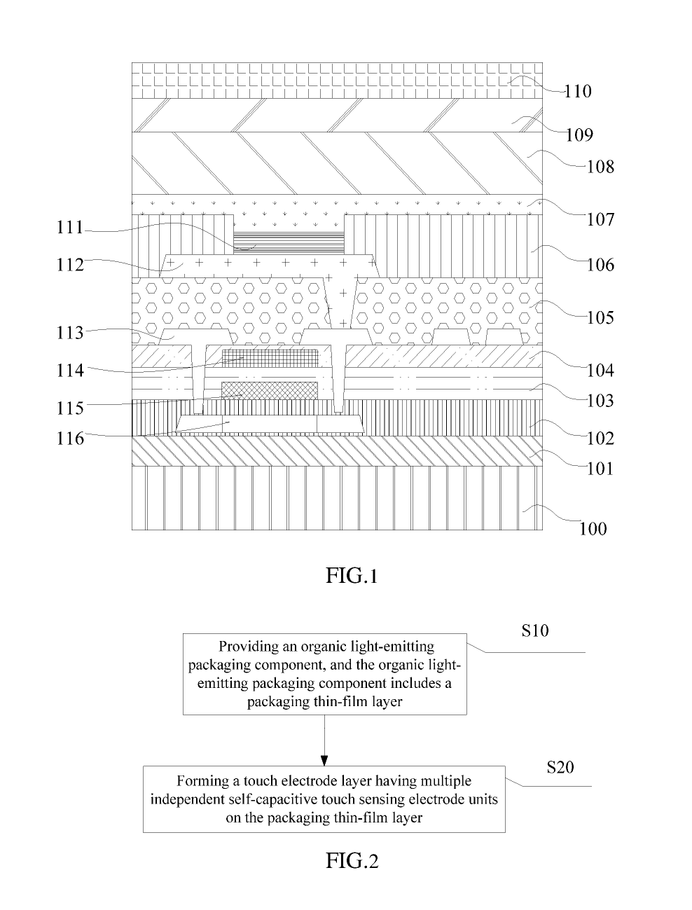

With reference to FIG. 2, FIG. 2 is a flow chart of a manufacturing method for an organic light-emitting display according to an embodiment of the present invention. The manufacturing method includes following steps:

S10: providing an organic light-emitting packaging component, and the organic light-emitting packaging component includes a packaging thin-film layer.

S20: forming a touch electrode layer having multiple independent self-capacitive touch sensing electrode units on the packaging thin-film layer.

Specifically, the method for forming a touch electrode layer having multiple independent self-capacitive touch sensing electrode units on the packaging thin-film layer includes: depositing an entire surface of a metal layer on the packaging thin-film layer; then, patterning the metal layer through a mask having a specific pattern.

More specifically, firstly, depositing an entire surface of a metal layer on the packaging thin-film layer of the organic light-emitting packaging component, and patterning the metal layer through a mask having a specific pattern to form multiple touch sensing electrode units. The organic light-emitting packaging component includes a pixel definition layer. All of the metal meshes are formed at pixel intervals of the pixel definition layer. Traces of the metal meshes all avoid passing through the pixel regions so that the optical display effect will not be affected. Between adjacent metal meshes, an electrically disconnected point is formed so that the metal meshes are electrically isolated with each other so as to form independent self-capacitive touch sensing units. Each of the independent self-capacitive touch sensing units is led out through one or more metal lead wires. Each metal lead wire is a portion of the metal mesh, and the metal lead wire is located at a pixel interval of the pixel definition layer.

Optionally, the method for forming the independent self-capacitive touch sensing units on the packaging thin-film layer includes: forming a metal mask having a specific pattern on the packaging thin-film layer through a deposition way. The organic light-emitting packaging component includes a pixel definition layer. All of the metal meshes are formed at pixel intervals of the pixel definition layer. Traces of the metal meshes all avoid passing through the pixel regions so that the optical display effect will not be affected. Between adjacent metal mesh, an electrically disconnected point is formed so that the metal meshes are electrically isolated with each other so as to form independent self-capacitive touch sensing units. Each of the independent self-capacitive touch sensing units is led out through one or more metal lead wires. Each metal lead wire is a portion of the metal mesh, and the metal lead wire is located at a pixel interval of the pixel definition layer.

Specifically, a material of the metal mesh can be any one of silver, titanium, aluminum and molybdenum in order to ensure that each of the metal meshes has a good conductivity and flexibility. Of course, in another embodiment, the material of the metal mesh can be other metal material having a good conductivity and flexibility.

In the present embodiment, the touch electrode layer includes multiple metal meshes and lead wires. The multiple metal meshes form a metal mesh layer, and the touch electrode layer is formed by the metal mesh layer having a single-layered structure. Accordingly, the driving electrode and the sensing electrode are not required so that only one mask is required in order to decrease the manufacturing process and decreasing the manufacturing cost.

Comparing with the conventional art, the organic light-emitting display manufactured by the present embodiment can realize an integrated touch control and display in order to decrease a thickness of the entire product, be beneficial for lightweight and be beneficial for flexibility.

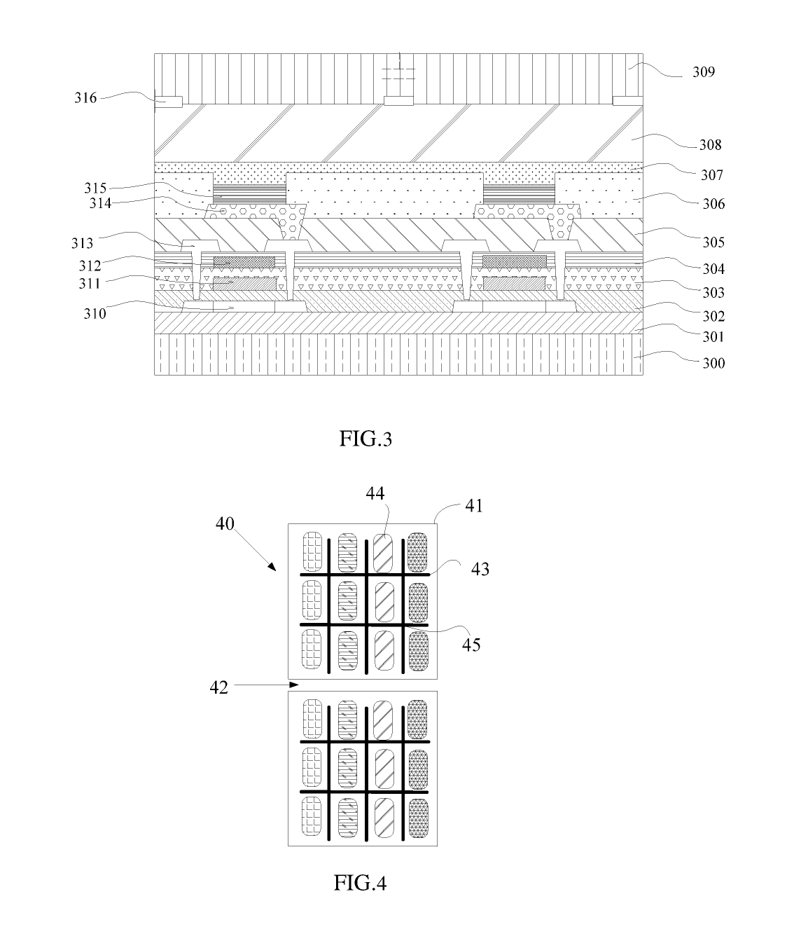

FIG. 3 is a schematic diagram of an organic light-emitting display according to an embodiment of the present invention. The organic light-emitting display includes an organic light-emitting packaging component and a touch electrode layer 316. Wherein, the organic light-emitting packaging component includes a packaging thin film layer 308, and the touch electrode layer 316 is formed on the packaging thin film layer 308. The touch electrode layer 316 has multiple independent self-capacitive touch sensing electrode units 40. The organic light-emitting packaging component includes following parts: an alignment film 300, a buffering region 301, a first gate insulation layer 302, a second gate insulation layer 303, a dielectric layer 304, a planarization layer 305, a pixel definition layer 306, a cathode layer 307, a packaging thin film layer 308, a covering window plate 309, an active region 310, a first GE layer 311, a second GE layer 312, an electron transport layer 313, a spacer 314 and an organic light-emitting display 315.

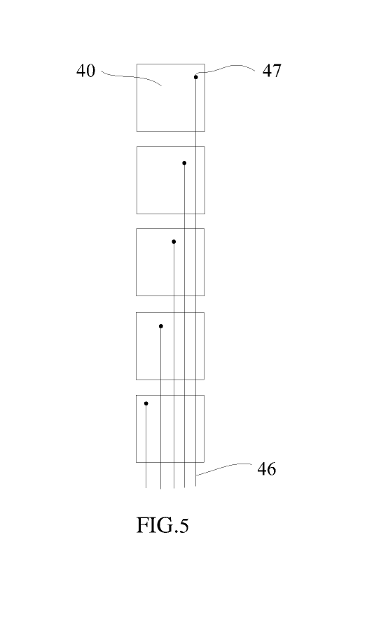

With reference to FIG. 4, and FIG. 4 is a schematic diagram of touch sensing electrode unit of the organic light-emitting display according to an embodiment of the present invention. The touch sensing electrode unit 40 includes a metal mesh 41, between adjacent metal meshes 41, an electrically disconnected point 42 is formed so that the metal meshes are electrically isolated with each other so as to form independent self-capacitive touch sensing units. The traces 43 of each metal mesh 41 are formed at intervals of the pixels of the pixel definition layer 44 so that an optical display effect will not be affected. An intersection location of the traces 43 of each metal mesh 41 is connected through a first vias 45.

With reference to FIG. 5, the touch sensing electrode unit 40 is led out through one or more lead wires 46. Each metal lead wire 46 is a portion of the metal mesh 41, and the lead wire 46 is located at a pixel interval of the pixel definition layer 44. The touch sensing electrode unit 40 is connected to the lead wire 46 through a second vias 47.

The organic light-emitting display of the present embodiment integrates the touch electrode layer having independent self-capacitive touch sensing electrode units into an upper portion of the organic light-emitting display. Through detecting variation amount of the mutual capacitance of the driving electrode and sensing electrode, a location of the finger is detected and a corresponding operation is executed. Accordingly, the present invention can realize an integrated touch control and display in order to decrease a thickness of the entire product, be beneficial for lightweight and be beneficial for flexibility.

The organic light-emitting display of the present embodiment can be applied into a display device. In the organic light-emitting display, the touch electrode layer having independent self-capacitive touch sensing electrode units is integrated into an upper portion of the organic light-emitting display in order to decrease a thickness of the entire product, be beneficial for lightweight and be beneficial for flexibility.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A manufacturing method for an organic light-emitting display, comprising steps of:
providing an organic light-emitting packaging component, wherein the organic light-emitting packaging component includes a packaging thin-film layer; and
depositing an entire surface of a metal layer on the packaging thin-film layer; patterning the metal layer through a mask having a specific pattern in order to form a touch electrode layer having multiple independent self-capacitive touch sensing electrode units on the packaging thin-film layer;
wherein, the touch electrode layer includes multiple metal meshes, and between adjacent metal meshes, an electrically disconnected point is formed.

2. The manufacturing method according to claim 1, wherein, the organic light-emitting packaging component includes a pixel definition layer having multiple pixels, and mesh traces of each metal mesh are formed at intervals of the pixels of the pixel definition layer.

3. The manufacturing method according to claim 1, wherein, a material of each metal mesh is any one of silver, titanium, aluminum and molybdenum.

4. The manufacturing method according to claim 1, wherein, each independent self-capacitive touch sensing electrode unit is led out through one or more lead wires.

5. A manufacturing method for an organic light-emitting display, comprising steps of:
providing an organic light-emitting packaging component, wherein the organic light-emitting packaging component includes a packaging thin-film layer; and
forming a touch electrode layer having multiple independent self-capacitive touch sensing electrode units on the packaging thin-film layer.

6. The manufacturing method for an organic light-emitting display according to claim 5, wherein,
the step of forming a touch electrode layer having multiple independent self-capacitive touch sensing electrode units on the packaging thin-film layer comprises: depositing an entire surface of a metal layer on the packaging thin-film layer first; then, patterning the metal layer through a mask having a specific pattern.

7. The manufacturing method for an organic light-emitting display according to claim 5, wherein,
the step of forming a touch electrode layer having multiple independent self-capacitive touch sensing electrode units on the packaging thin-film layer comprises: forming a metal mask having a specific pattern on the packaging thin-film layer through a deposition way.

8. The manufacturing method for an organic light-emitting display according to claim 5, wherein, the touch electrode layer includes multiple metal meshes, and between adjacent metal meshes, an electrically disconnected point is formed.

9. The manufacturing method for an organic light-emitting display according to claim 8, wherein, the organic light-emitting packaging component includes a pixel definition layer having multiple pixels, and mesh traces of each metal mesh are formed at intervals of the pixels of the pixel definition layer.

10. The manufacturing method for an organic light-emitting display according to claim 8, wherein, a material of each metal mesh is any one of silver, titanium, aluminum and molybdenum.

11. The manufacturing method for an organic light-emitting display according to claim 5, wherein, each independent self-capacitive touch sensing electrode unit is led out through one or more lead wires.

12. An organic light-emitting display, comprising:
an organic light-emitting packaging component, wherein, the organic light-emitting packaging component includes a packaging thin-film layer;
a touch electrode layer disposed on the packaging thin-film layer, wherein the touch electrode layer has multiple independent self-capacitive touch sensing electrode units.

13. The organic light-emitting display according to claim 12, wherein, the touch electrode layer includes multiple metal meshes, and between adjacent metal meshes, an electrically disconnected point is formed.

14. The organic light-emitting display according to claim 13, wherein,
the organic light-emitting packaging component includes a pixel definition layer having multiple pixels, and mesh traces of each metal mesh are formed at intervals of the pixels of the pixel definition layer.

15. The organic light-emitting display according to claim 12, wherein, each independent self-capacitive touch sensing electrode unit is led out through one or more lead wires.

16. The organic light-emitting display according to claim 13, wherein,
a material of each metal mesh is any one of silver, titanium, aluminum and molybdenum.
